(19) United States
(12) Patent Application Publication
(10) Pub. No.: US 2007/0132048 A1
(43) Pub. Date: Jun. 14, 2007

(54) Multi-Layer Device

(75) Inventor: Trond Westgaard, -3192 Horten (NO)

Correspondence Address: EDELL, SHAPIRO & FINNAN, LLC, 1901 RESEARCH BOULEVARD, SUITE 400, ROCKVILLE, MD, 20850, US

(73) Assignee: INFINEON TECHNOLOGIES SENSONOR AS, Horton (NO)

(21) Appl. No.: 11/539,774

(22) Filed: Oct. 9, 2006

(30) Foreign Application Priority Data
Dec. 14, 2005 (EP) 05257719.4

(51) Int. Cl. H01L 29/84

(52) U.S. Cl. 257/419; 438/53

(57) ABSTRACT

A multi-layer device includes a first layer with a micro-mechanical component formed thereon. The device also includes first and second sealing layers, with the first layer sandwiched between the first and second sealing layers and anodically bonded thereto such that a cavity is defined therein. An electrode is provided within the cavity for reducing UV emission. The electrode is formed on at least a part of a surface of the second sealing layer internal to the cavity and arranged to be in electrical contact with the first layer.

### CROSS REFERENCE TO RELATED APPLICATIONS

This application claims priority under 35 U.S.C. §119 to Application No. EP 05257719.4 filed on Dec. 14, 2005, entitled “Multi-Layer Device,” the entire contents of which are hereby incorporated by reference.

### FIELD OF THE INVENTION

The present invention relates to a multi-layer device.

### BACKGROUND

There are currently many systems such as micro electromechanical systems (MEMS), which require silicon and glass to be bonded together in such a way that a sealed cavity is formed. The silicon and glass layers are generally bonded via anodic bonding which is performed at elevated temperatures, i.e., in the region of 650 K, and high voltages, i.e., 500 to 1000V.

Micromechanical components are well known in the art. In some applications it is beneficial to fill the sealed cavity with a gas. In this case, due to the electric field present during the bonding process, any available free electrons may be accelerated to cause ionization of the gas. This gives rise to the problem that the ionized gas emits ultraviolet (UV) radiation which may change surface properties inside the cavity or negatively influence the stability of electronic components inside the cavity.

One way to try and minimize this problem is to reduce the bonding voltage such that the UV emission is reduced. However this does not eliminate UV emission completely and if the voltage is reduced too much the bonding process becomes unreliable.

### SUMMARY

The present invention solves at least the above problem. According to the device there is provided a multi-layer device including:

a first layer with a micro-mechanical component formed thereon;

first and second sealing layers, wherein the first layer is sandwiched between the first and second sealing layers and bonded thereto to define a cavity therein; and

an electrode,

characterized by:

the first layer being anodically bonded to the first and second sealing layers;

a gas being provided within the cavity; and

the electrode being formed on at least a part of a surface of the second sealing layer internal to the cavity and arranged to be in electrical contact with the first layer, such that the electrode reduces UV emission.

According to the present invention there is further provided a method for manufacturing a multi-layer device, the method including:

providing a first layer with a micro-mechanical component formed thereon; and

anodically bonding a first sealing layer to the first layer in vacuum,

characterized by:

anodically bonding a second sealing layer to the first layer in the presence of a gas to define a cavity with the gas being captured inside; and

an electrode being formed on at least a part of a surface of the second sealing layer internal to the cavity and arranged to be in contact with the first layer during bonding of the second sealing layer to the first layer such that the electrode reduces UV emission.

The above and still further features and advantages of the present invention will become apparent upon consideration of the following definitions, descriptions and descriptive figures of specific embodiments thereof, wherein like reference numerals in the various figures are utilized to designate like components. While these descriptions go into specific details of the device, it should be understood that variations may and do exist and would be apparent to those skilled in the art based on the descriptions herein.

### BRIEF DESCRIPTION OF THE DRAWINGS

The invention is explained in more detail below with reference to exemplary embodiments, where:

FIG. 1 shows a cross-sectional view of an example multi-layer device according to the present invention;

FIG. 2 shows a partial cross-sectional view of an alternative example multi-layer device according to the present invention;

FIG. 3 is a diagram of an example electrode structure according to the example of the present invention shown in FIG. 1; and

FIG. 4 is a diagram of an example electrode structure according to the example according to the present invention shown in FIG. 2.

### DETAILED DESCRIPTION

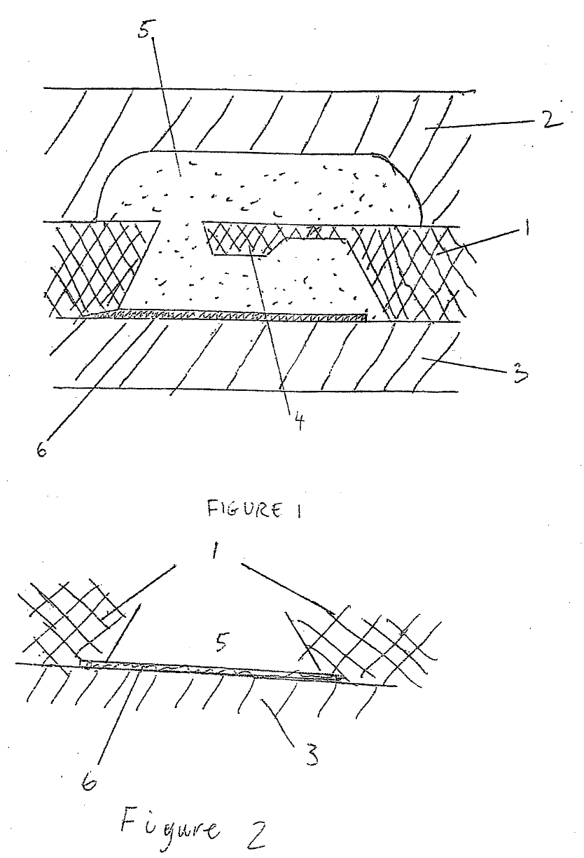

Referring to FIG. 1, a multi-layer device includes a silicon layer 1 sandwiched between a first and a second glass sealing layer 2, 3. The silicon layer 1 has a micro-mechanical component 4 formed thereon and the layers 1, 2, 3 are arranged such that a cavity 5 is formed around the active micro-mechanical component 4. This cavity 5 is filled with gas.

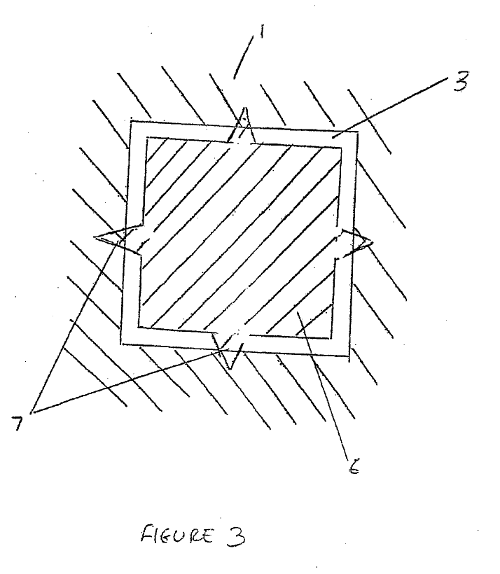

Referring to FIGS. 1 to 4, an electrode 6 is formed on top of the second sealing layer 3. This electrode 6 is at a distance approaching the wafer thickness (typically 100 μm to 1000 μm) from the micro-mechanical component, which distinguishes it from electrodes for capacitive read-out or for electro-static actuation that would be at a distance of 10 μm or less. The electrode 6 may cover the entire exposed glass area and extend into the contact area between the silicon layer 1 and the second sealing layer 3. An example of this geometry is shown in FIG. 2 and FIG. 4.

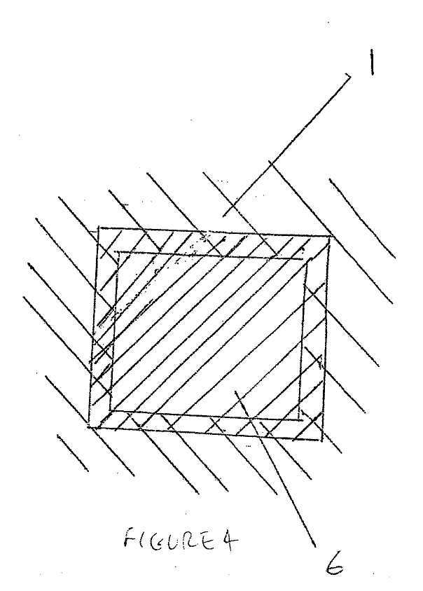

Alternatively, the electrode area 6 may be reduced to the area where the active structure 4 is located, with the electrode extending outside this area with a distance approximately equal to the wafer thickness or longer. An example of this geometry is shown in FIG. 1 and FIG. 3. With this electrode design contact structures 7, shown in FIG. 3, bring the electrode pattern 6 into contact with the silicon layer 1 surrounding the cavity 5. This design interferes less with the bonding area, which is beneficial as most designs will try to minimize the total area of the device while maintaining sufficient bonding areas.

With both types of electrode designs the electrode potential is fixed at the silicon potential during anodic bonding. There is therefore low electric field strength between metallized areas 6 of the surface of the second sealing layer 3 and the silicon layer 1. Since there is no UV emission in the first bonding process when gas is not present and only low UV emission is produced from these volumes of weak field during the second bonding process, the exposure to UV radiation is significantly reduced.

While the invention has been described in detail with reference to specific embodiments thereof, it will be apparent to one of ordinary skill in the art that various changes and modifications can be made therein without departing from the spirit and scope thereof. Accordingly, it is intended that the present invention covers the modifications and variations of this described device provided they come within the scope of the appended claims and their equivalents.

What is claimed is:

1. A multi-layer device comprising:
a first layer including a micro-mechanical component formed thereon;
first and second sealing layers, wherein the first layer is sandwiched between and anodically bonded to the first and second sealing layers such that a cavity is defined at a location in which the first layer is bonded to the first and second sealing layers;
a gas provided within the cavity; and
an electrode formed on at least a surface portion of the second sealing layer internal to the cavity and in electrical contact with the first layer such that the electrode reduces UV emission.

2. The device according to claim 1, wherein the first layer comprises silicon.

3. The device according to claim 1, wherein the first and second sealing layers comprise glass.

4. The device according to claim 1, wherein the distance between the micro-mechanical component and any portion of the electrode is at least about 100 μm.

5. The device according to claim 1, wherein the electrode comprises at least one electrical contact structure, and the electrode is further configured such that only the at least one electrical contact structure and no other portion of the electrode is arranged to contact at least one anodically bonded part of a surface of the second sealing layer within the cavity.

6. The device according to claim 1, wherein the electrode is formed on the entire surface of the second sealing layer disposed within the cavity.

7. A method for manufacturing a multi-layer device, the method comprising:
providing a first layer including a micro-mechanical component formed thereon;
anodically bonding a first sealing layer to the first layer in a vacuum;
anodically bonding a second sealing layer to the first layer in the presence of a gas so as to form a gas filled cavity at a location in which the first layer is bonded to the first and second sealing layers; and
forming an electrode on at least a part of a surface of the second sealing layer within the cavity and in contact with the first layer during bonding of the second sealing layer to the first layer such that the electrode reduces UV emission.

8. The method according to claim 7, wherein the first layer comprises silicon.

9. The method according to claim 7, wherein the first and second sealing layers comprise glass.

10. The method according to claim 7, wherein the second sealing layer is bonded to the first layer such that the distance between the micro-mechanical component and any portion of the electrode is at least about 100 μm.

11. The method according to claim 7, wherein the electrode comprises at least one electrical contact structure, and the electrode is further configured such that only the at least one electrical contact structure is in contact with the first layer during bonding.

12. The method according to claim 7, wherein the electrode is formed on the entire surface of the second sealing layer disposed within the cavity.
